(19) United States
(12) Patent Application Publication
(10) Pub. No.: US 2026/0160418 A1
(43) Pub. Date: Jun. 11, 2026

(54) PORTABLE BIOMETRIC LIGHTER

(71) Applicant: John Gibson, Mundelein, IL (US)

(72) Inventor: John Gibson, Mundelein, IL (US)

(21) Appl. No.: 19/181,241

(22) Filed: Apr. 16, 2025

Related U.S. Application Data
(63) Continuation of application No. 18/239,115, filed on Aug. 28, 2023, now Pat. No. 12,298,005.
Application No. 18/239,115 is a continuation of application No. 17/200,670, filed on Mar. 12, 2021, now Pat. No. 11,774,096.
Application No. 17/200,670 is a continuation of application No. 16/705,389, filed on Dec. 6, 2019, now Pat. No. 10,969,102.
Application No. 16/705,389 is a continuation of application No. 15/702,252, filed on Sep. 12, 2017, now Pat. No. 10,502,419.

(51) Int. Cl. F23Q 2/16; F23Q 2/32; F23Q 3/00; G06V 40/13; H10W 42/00

(52) U.S. Cl. CPC F23Q 2/164; F23Q 2/16; F23Q 2/32; F23Q 3/002; G06V 40/13; H10W 42/121

(57) ABSTRACT

A portable biometric lighter device (100) generally involving a control unit (210), a biometric sensor, such as a fingerprint sensor (140), wherein the biometric sensor is configured to scan a biometric data of a user and is operably coupled to the control unit (210), and an ignition element, wherein the ignition element is activated by the control unit (210) upon a match of the scanned biometric data of the user and a biometric data of an authorized user that is stored in a memory device.

This application is a continuation of U.S. application Ser. No. 18/239,115, filed Aug. 28, 2023, which is a continuation of U.S. application Ser. No. 17/200,670, filed Mar. 12, 2021, now U.S. Pat. No. 11,774,096, which is a continuation of U.S. application Ser. No. 16/705,389, filed Dec. 6, 2019, now U.S. Pat. No. 10,969,102, which is a continuation of U.S. application Ser. No. 15/702,252, filed Sep. 12, 2017, now U.S. Pat. No. 10,502,419, each of which is incorporated in its entirety herein by reference.

### TECHNICAL FIELD

The present invention generally technically relates to portable biometric lighter devices, and more specifically, to portable lighters using biometric data to prevent unauthorized usage. The present invention technically relates to devices ensuring that a user of a portable lighter is an authorized user and that a minor will not be able to activate the portable lighter.

### BACKGROUND ART

Portable lighters are commonly used for lighting cigarettes, tobacco pipes, cigars, charcoal grills, pilots of gas appliances, fireplaces, water-heaters, and campfires. These portable lighters are typically activated by a user opening a cap, manually flicking a wheel to create a spark, and depressing a button that allows lighter fluid to flow. Unfortunately, these typical portable lighters have no safety mechanism to prevent an unauthorized user, such as a child, from activating a flame and accidently causing fire and bodily injuries, or other unauthorized users from intentionally causing fires. While some portable lighters have incorporated safety precaution mechanisms to deal with the possibility of misuse of a portable lighter, such examples include a portable lighter that incorporates a gas valve button that will not allow lighter fluid to flow unless a force of an adult finger is applied to the gas valve button, and a portable lighter that incorporates an electronic alphanumeric keypad to control access to the portable lighter's ignition mechanisms. These examples, however, have their shortcomings in that they are not user-friendly for the authorized user and the safety mechanisms that are in place can easily be tampered by a child.

With respect to the portable lighter that incorporates a gas valve button, requiring the force of an adult's finger, an authorized adult user may not always be able to apply the force necessary to activate the button or an older aged child may have the ability to apply a force that mimics that of an adult. With respect to the alphanumeric keypad and requiring a security code to activate the lighter, an authorized user may forget the security code or a child can gain access to the code by merely viewing the authorized user enter the security code.

Thus, a long-felt need exists in the art for a portable lighter that is able to easily recognize the authorized user of the portable lighter and that is able to prevent an unauthorized user, e.g., a child, from mimicking the authorized user. The incorporation of a biometric sensor and biometric data, such as a fingerprint sensor and a fingerprint data, satisfies the aforementioned needs.

### SUMMARY OF THE INVENTION

In one embodiment, the present invention involves as a portable biometric lighter device, comprising: a control unit; a biometric sensor, wherein the biometric sensor is configured to scan a biometric data of a user and is operably coupled to the control unit; and an ignition element, wherein the ignition element is activated by the control unit upon a match of the scanned biometric data of the user and a biometric data of an authorized user that is stored in a memory device. While the present invention focuses on portable biometric lighter devices, it is not limited to portable biometric lighter devices, as it can be applied to countless other portable flammable devices and systems that require safety precautions. In addition, while the present invention comprises a fingerprint sensor as the biometric sensor and a fingerprint as the biometric data, by example only, other types of biometric sensors and other types of biometric data can be incorporated, such as a voice sensor and voice data, an age detector and an age data, or a facial image sensor and a facial image data. The present invention also involves a method of fabrication of the portable biometric device.

In another embodiment, the invention can be characterized as a method for controlling access to a portable biometric lighter device, comprising the steps of: scanning a biometric data from an authorized user; storing in a memory device the biometric data from the authorized user; scanning a biometric data from a user; determining a match between the scanned biometric data from the authorized user and the scanned biometric data from the user; and activating the portable biometric lighter device upon the match between the scanned biometric data from the authorized user and the scanned biometric data from the user.

In yet another embodiment, the invention involves a portable biometric lighter device, comprising a device for scanning a biometric data from an authorized user; a device for scanning a biometric data from a user; and a device for activating the portable biometric lighter device upon a match of the biometric data from the authorized user and the biometric data from the user.

In some embodiments, a portable biometric lighter device, comprises a control unit operably coupled to an igniter. The igniter is coupled to a flammable power source ignitable upon operation of the igniter. The lighter further comprises a memory device coupled to the control unit and configured to store biometric data including at least one fingerprint of at least one authorized user, and a push-button including a biometric sensor, the movable cap configured to move between a deactivated position and an activated position and to activate the biometric sensor and a gas lever when the movable cap is moved toward the activated position. The biometric sensor is operably connected to the control unit and configured to scan a fingerprint of a user. The lighter further comprises a light source configured to provide status of the biometric sensor and to indicate, to the user, that the biometric sensor is ready to scan biometric data of the user and an igniter operably coupled to the control unit and configured to ignite the flammable power source to produce a flame in response to being activated by the control unit upon a determination by the control unit that the fingerprint of the user scanned by the biometric sensor matches the biometric data of the authorized user stored in a memory device.

In some embodiments, a method for lighting a portable biometric lighter device comprise: providing a control unit operably coupled to an igniter, the igniter coupled to a flammable power source ignitable upon operation of the igniter; providing a memory device coupled to the control unit storing biometric data including at least one fingerprint of at least one authorized user; providing a push-button including a biometric sensor, the movable cap configured to move between a deactivated position and an activated position and to activate the biometric sensor and a gas lever when the movable cap is moved toward the activated position, the biometric sensor being operably connected to the control unit and configured to scan a fingerprint of a user; providing a light source configured to provide status of the biometric sensor and to indicate, to the user, that the biometric sensor is ready to scan biometric data of the user; providing an igniter operably coupled to the control unit and configured to ignite the flammable power source to produce a flame in response to being activated by the control unit; scanning biometric data of the user via the biometric sensor activated after the push-button is moved to the activated position; determining, via the control unit that the fingerprint of the user scanned by the biometric sensor matches the biometric data of the authorized user stored in a memory device; and activating, via the control unit, the igniter in order to ignite the flammable power source via the activated igniter.

In some embodiments, a portable biometric lighter device, comprises a control unit operably coupled to an igniter. The igniter is coupled to a flammable power source wherein the flammable power source is ignited upon operation of the igniter. The lighter further includes a memory device storing biometric data including at least one fingerprint of at least one authorized user and a body having a cover and including a biometric sensor. The cover is configured to move between a closed position and an open position and to activate the biometric sensor and a gas lever when the movable cover is moved toward the open position. The biometric sensor is operably connected to the control unit and configured to scan a fingerprint of a user. The lighter further includes a light source configured to provide status of the biometric sensor and to indicate, to the user, that the biometric sensor is ready to scan biometric data of the user and an igniter operably coupled to the control unit and configured to ignite the flammable power source to produce a flame in response to being activated by the control unit upon a determination by the control unit that the fingerprint of the user scanned by the biometric sensor matches the biometric data of the authorized user stored in a memory device.

In some embodiments, the method for lighting a portable biometric lighter device includes: providing a control unit operably coupled to an igniter, the igniter coupled to a flammable power source wherein the flammable power source is ignited upon operation of the igniter; providing a memory device storing biometric data including at least one fingerprint of at least one authorized user; providing a body having a cover and including a biometric sensor, the cover configured to move between a closed position and an open position and to activate the biometric sensor and a gas lever when the movable cover is moved toward the open position, the biometric sensor being operably connected to the control unit and configured to scan a fingerprint of a user; providing a light source configured to provide status of the biometric sensor and to indicate, to the user, that the biometric sensor is ready to scan biometric data of the user; providing an igniter operably coupled to the control unit and configured to ignite the flammable power source to produce a flame in response to being activated by the control unit; scanning biometric data of the user via the biometric sensor activated after the cover is moved to the open position; determining, via the control unit that the fingerprint of the user scanned by the biometric sensor matches the biometric data of the authorized user stored in a memory device; and activating, via the control unit, the igniter in order to ignite the flammable power source via the activated igniter.

Advantages of the present invention include, but are not limited to, providing enhanced safety to incendiary devices, decreasing the probability of accidental fire or arson, decreasing the probability of personal injury, decreasing the probability of property damage, and decreasing the cost of fire insurance. Other features of the present invention are disclosed, or are apparent, in the section entitled “Mode(s) for Carrying-Out the Invention,” disclosed, infra.

### BRIEF DESCRIPTION OF THE DRAWINGS

For a better understanding of the present invention, reference is made to the below-referenced accompanying Drawing(s). Reference numbers refer to the same or equivalent parts of the present invention throughout the several figures of the Drawing(s).

FIG. 1 is a frontal perspective view of a portable biometric lighter, showing a cap, a body, a body cover, a fingerprint sensor, a light emitting diode (LED), a label, and a set switch, in accordance with the present invention.

FIG. 2 is a partial exploded view of the portable biometric lighter, in accordance with the embodiment of FIG. 1, showing a label, a body cover, a fingerprint sensor, an LED, a control unit, a plurality of power lines and control lines, a plurality of LED apertures, and a plurality of fingerprint sensor apertures.

FIG. 3 is a cross-sectional view of the portable biometric lighter, in accordance with the embodiment of FIG. 1, showing a cap, a body, a fingerprint sensor, an LED, a control unit, a plurality of power lines, a plurality of control lines, a set switch, a gas lever, an active switch, a lighter fluid valve, a nozzle, a pulse igniter, a pole, a lighter fluid, and a power source.

FIG. 4 is a flowchart showing the steps of a method of teaching an authorized user's fingerprint to the portable biometric lighter, in accordance with the embodiment of FIG. 1.

FIG. 5 is a flowchart showing the steps of an alternative method of teaching an authorized user's fingerprint to the portable biometric lighter, in accordance with the embodiment of FIG. 1, wherein a prior fingerprint that is stored in a memory device is cleared upon the teaching of a new authorized user's fingerprint.

FIG. 6 is a flowchart showing the steps of igniting a flame for the portable biometric lighter, in accordance with the embodiment of FIG. 1.

FIG. 7 is a circuit diagram of the portable biometric lighter, in accordance with the embodiment of FIG. 1, showing a control unit, a power source, a control line, a set switch, an exemplary pulse igniter circuit, and an active switch.

FIG. 8 is an alternative circuit diagram of the portable biometric lighter, in accordance with the embodiment of FIG. 1.

FIG. 9 is a flowchart showing a method of fabricating a portable biometric lighter.

FIG. 10 is a side perspective view of a portable biometric lighter in accordance with some embodiments.

FIG. 11 is a bottom view of the portable biometric lighter of FIG. 10.

FIG. 12 is a side elevational view of the portable biometric lighter of FIG. 10 depicted in an activated condition and emitting a flame.

FIG. 13 is a functional block diagram illustrating the portable biometric lighter of FIG. 10 in accordance with some embodiments.

FIG. 14 is a flow chart diagram illustrating a method of igniting the portable biometric lighter of FIG. 10.

FIG. 15 is a front perspective view of a portable biometric lighter in accordance with some embodiments.

FIG. 16 is a bottom view of the portable biometric lighter of FIG. 15.

FIG. 17 is a front perspective view of the portable biometric lighter of FIG. 15 depicted in an activated condition and emitting a flame.

FIG. 18 is a functional block diagram illustrating the portable biometric lighter of FIG. 15 in accordance with some embodiments.

FIG. 19 is a flow chart diagram illustrating a method of igniting the portable biometric lighter of FIG. 15.

### MODE(S) FOR CARRYING-OUT THE INVENTION

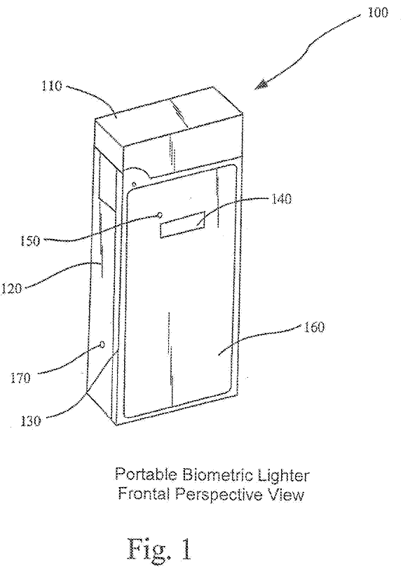

Referring to FIG. 1, a front perspective view of a portable biometric lighter device 100 shows a cap 110, a body 120, a body cover 130, a fingerprint sensor 140, an LED 150, a label 160, and a set switch 170. The portable biometric lighter device 100 as shown in FIG. 1 is that of a cigarette/cigar lighter type, by example only. Other examples of alternative embodiments of the portable biometric lighter device 100, not shown, can be that of a utility lighter, a barbeque lighter, and an oil-lighter. The portable biometric lighter device 100 can be that of a disposable type, e.g., wherein the user disposes of the portable biometric lighter 100 once the lighter fluid or the power source is expended, or a reusable type, e.g., wherein the user can replace the power source and/or refill the lighter fluid. The lighter fluid may comprise at least one flammable component, such a butane gas, aliphatic hydrocarbon, a kerosene, a paraffinic hydrocarbon, a napthenic hydrocarbon, a benzene, a terpene, a terpenoid, a methanol, an ethanol, a propanol, a butanol, an aliphatic naptha, a hexamine, a lacolene, and the like.

The portable biometric lighter device 100, as shown, comprises a cap 110. The cap 110 is hingedly coupled to the body 120 and is configured to prevent accidental activation of both a gas valve lever (not shown) and an active switch (not shown). The cap 110 may also be configured to activate the fingerprint sensor 140 and allow lighter fluid (not shown) to flow when it is flipped open. The cap 110 is typically made of the same material as the body 120. While FIG. 1 shows the biometric lighter 100 with a cap 110, alternative embodiments may not comprise the cap 110.

The body 120, as shown in FIG. 1, is of a rectangular shape; however, alternative embodiments of the portable biometric lighter 100 may involve other shapes, such as a square shape, a circular shape, a cylindrical or tubular shape, or an oval shape. The body 120 comprises any material, such as a polymer, a plastic, a metal, a heat-resistant material, and a composite. The body 120 is configured to house at least one of the following elements: a lighter fluid (not shown), a set switch 170, a fingerprint sensor 140, an LED 150, a control unit (not shown), a plurality of control lines (not shown), a power source (not shown), and a lighter fluid valve (not shown). The body 120 comprises an aperture for providing access to the set switch 170.

The body cover 130 comprises the same shape as that of the body 120 of the portable biometric lighter device 100, and also typically comprises the same material as that of the body 120. The body cover 130 is configured to cover the aforementioned housed elements (not shown) in the body 130. The body cover 130 comprises apertures for access to a fingerprint sensor 140 and an LED 150.

A biometric sensor, e.g., the fingerprint sensor 140, is operably coupled to a control unit (not shown). The biometric sensor is housed in the body 120 and is configured to scan and optionally store, in a memory device (not shown), an authorized user's biometric data, e.g., an authorized user's fingerprint, and a user's biometric data, e.g., a user's fingerprint, through an aperture of the body cover 130.

The LED 150 is operably coupled to the control unit (not shown). In addition, the LED 150 is configured to provide indications to a user, via blinking and/or indicating a color, such indications including the status of the portable biometric lighter functions, e.g., setup/teaching mode, low battery, failed scan, and incorrect match, by example only.

The label 160 is adhesively attached to the body cover 130. The label 160 comprises apertures for the fingerprint sensor 140 and the LED 150. The label 160 is configured to allow a manufacturer to place design features (not shown) or brand indicators (not shown), by example only. The label 160 further comprises apertures for accommodating a fingerprint sensor 140 and an LED 150.

The set switch 170 is operably connected to the control unit (not shown) and is housed in the body 120. Accessing the set switch 170 is performed through at least one aperture of the body 120. The set switch 170 is configured to activate the control unit (not shown) for accepting a new fingerprint, and to optionally erase a prior fingerprint from a memory device (not shown) if the control unit (not shown) is configured to allow erasing prior fingerprint and accepting new fingerprint.

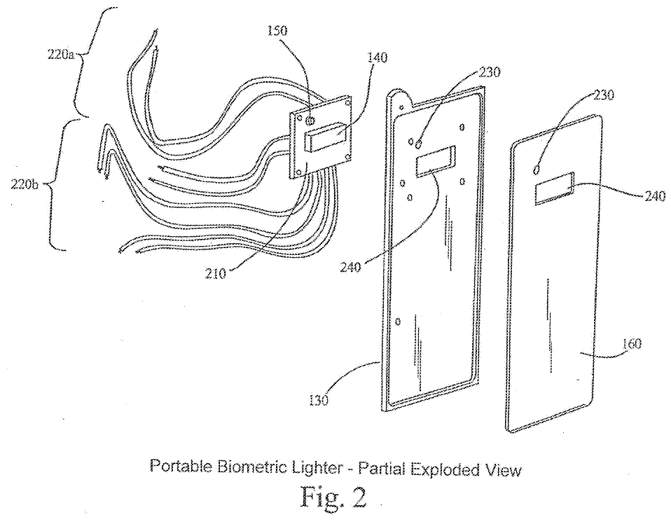

Referring to FIG. 2, a partial exploded view of the portable biometric lighter device 100 is shown, in accordance with the embodiment of FIG. 1, the device 100 comprising a label 160, a body cover 130, a biometric sensor, e.g., a fingerprint sensor 140, an LED 150, a control unit 210, a plurality of power lines 220a and control lines 220b, a plurality of LED apertures 230, and a plurality of fingerprint sensor apertures 240.

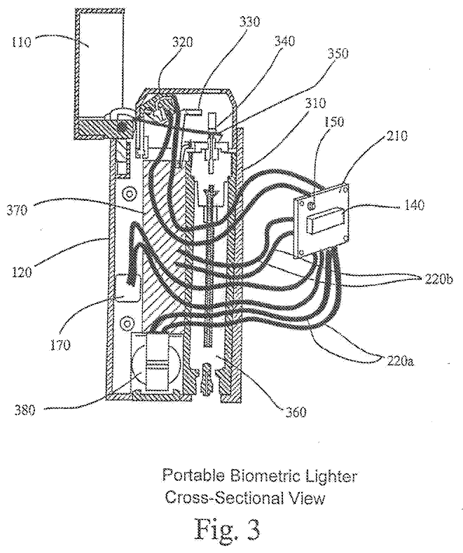

Referring to FIG. 3, a cross-sectional view of the portable biometric lighter device 100 is illustrated, in accordance with the embodiment of FIG. 1. The device 100 comprises a cap 110, a body 120, a biometric sensor, e.g., a fingerprint sensor 140, an LED 150, a control unit 210, a plurality of power lines 220a, a plurality of control lines 220b, a set switch 170, a gas lever 350, an active switch 320, a lighter fluid valve 310, a nozzle 340, a pulse igniter 370, a pole 330, a lighter fluid 360, and a power source 380. Alternatively, an electric gas valve (not shown) may be used in place of the cap 110.

A power source 380 is operably coupled to a control unit 210 and is housed within a body 120. The power source 380 can be a primary cell battery, a rechargeable battery, or a photo-voltaic cell, by example only. The power source 380 provides power to the control unit 210 and/or the fingerprint sensor 140 via a plurality of power lines 220a.

The active switch 320 is operably coupled to the fingerprint sensor 140 such that upon a user flipping open the cap 110, the gas lever 350 is pulled up and activates the active switch 320 via contact force or electromagnetic force. The active switch 320 upon activation then activates the fingerprint sensor 140 to read or scan a fingerprint. The gas lever 350 is also configured to lift the nozzle 340, which allows the lighter fluid 360 to be released from the lighter fluid valve 310, upon the user flipping open the cap 110.

A pulse igniter 370, such as a piezoelectric based circuit, is configured to produce a high voltage spark from a pole 330 to the nozzle 340 upon the control unit 210 determining a match between a scanned user's biometric data, such as the user's fingerprint and the authorized user's biometric data, e.g., authorized user's fingerprint, that is previously stored in a memory device (not shown). A flame is subsequently produced when the high voltage sparks come in contact with the lighter fluid 360 that is flowing through the lighter fluid valve 310 to the nozzle 340.

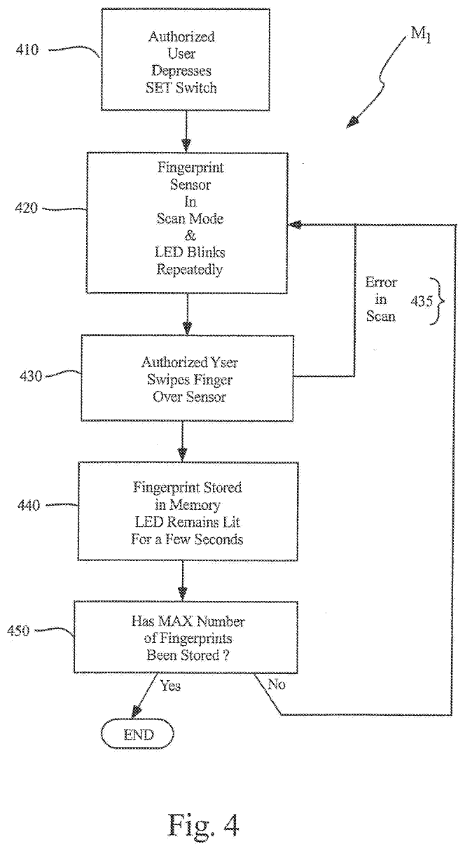

Referring to FIG. 4, a flowchart illustrates the steps of a method M₁ of setting-up/teaching an authorized user's biometric data, e.g., fingerprint, to the portable biometric lighter device 100, by way of a biometric lighter device 100, in accordance with the embodiment of FIG. 1. The first teaching step 410 comprises the step of an authorized user depressing a set switch 170. The second teaching step 420 comprises commencing periodic or repetitious blinking by an LED 150 to indicate that the fingerprint sensor 140 is ready to scan. The third teaching step 430 comprises the step of an authorized user swiping or depressing his or her finger, preferably the thumb or the index finger, over the fingerprint sensor 140. If an error in scanning the fingerprint occurs, the LED 150 continues to blink repeatedly as indicated by method step block 435. The fourth teaching step 440 comprises the fingerprint sensor 140 successfully scanning and storing fingerprint data in a memory device, wherein the LED 150 remains lit for a brief interval before extinguishing. According to block 450, this process of teaching may be repeated until a manufacturer pre-determined maximum number of fingerprints is stored, e.g., 4 fingerprints. In this embodiment, the stored fingerprints are not erasable or changeable.

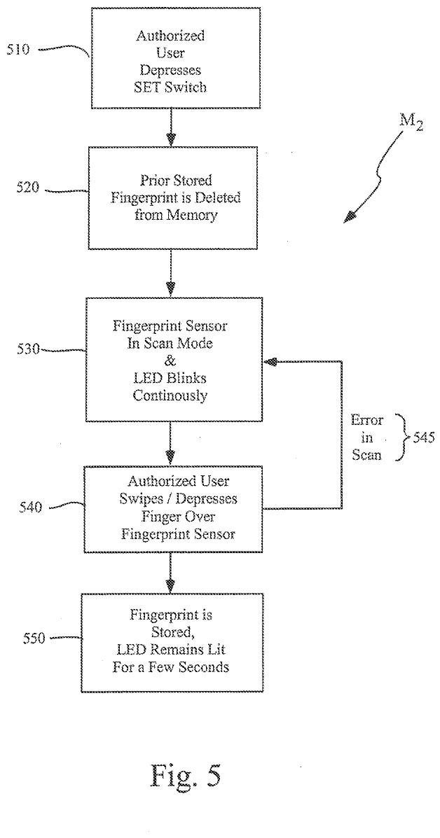

Referring to FIG. 5, a flowchart shows the steps of an alternative method M₂ of teaching an authorized user's fingerprint to the portable biometric lighter device 100, in accordance with the embodiment of FIG. 1, wherein prior fingerprint that being stored in a memory device is erased upon teaching of a new authorized user's fingerprint.

The first alternative teaching step 510 in the method M₂ involves an authorized user depressing/activating a set switch 170. Then the second alternative teaching step 520 comprises deleting prior stored fingerprint data of an authorized user from a memory device (not shown). The third alternative teaching step 530 comprises commencing periodic or repetitious blinking by an LED 150 to indicate that the fingerprint sensor 140 is ready to scan in new authorized user's biometric data, e.g., a fingerprint. The fourth alternative teaching step 540 comprises swiping by an authorized user's finger, preferably the thumb or the index finger, over the fingerprint sensor 140. If an error occurs in scanning the fingerprint, the LED 150 continues to blink repeatedly as indicated by method step 545. The fifth alternative teaching step 550 comprises successfully scanning and storing a fingerprint scan in a memory device (not shown) by the fingerprint sensor 140, wherein the LED 150 remains lit for a brief interval before extinguishing.

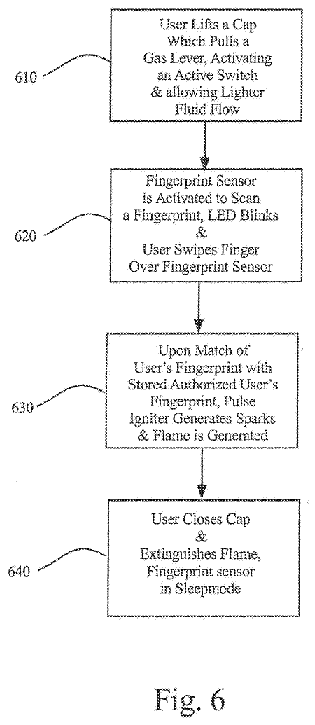

Referring to FIG. 6, a flowchart illustrates the steps of activating, e.g., igniting a flame, by the portable biometric lighter device 100, in accordance with the embodiment of FIG. 1. The first step of igniting a flame 610 comprises a user opening a cap 110, whereby a gas lever 350 is actuated, thereby actuating an active switch 320 via contact pressure or electromagnetic force. The actuation of the gas lever 350 also simultaneously causes a lifting of a nozzle 340, which allows the lighter fluid 360 to be released from the lighter fluid valve 310.

The second step 620 of igniting a flame comprises the active switch 320, activating, via a control unit 210, the fingerprint sensor 140 to read or to scan a fingerprint and to repeatedly blink an LED 150 indicating to the user that the fingerprint sensor 140 is in “scan” or “read” mode. The third step 630 of igniting the flame comprises the control unit 210 determining that the scanned fingerprint matches an authorized user's fingerprint that is stored in memory. If the scanned fingerprint matches an authorized user's fingerprint that is stored in memory, the control unit 210 will activate a pulse igniter 370, e.g., a piezoelectric based circuit, thereby generating a plurality of high voltage sparks through the pole 330 to the nozzle 340. A flame is thereby generated via lighter fluid 360 flowing through the nozzle 340. However, if the scanned fingerprint does not match an authorized user's fingerprint that is stored in memory, the LED 150 will blink in a red color and then subsequently in a green color as the fingerprint sensor 140 continues to read or scan a fingerprint.

While the embodiment in FIG. 6 involves the control unit 210 activating a pulse igniter 370 upon a fingerprint match, alternative embodiments may also involve the control unit 210 deactivating, via a solenoid and at least one of the following elements: a push button (not shown), a cap lock (not shown), the cap lock being releasable, a gas valve lock (not shown), an electric gas valve (not shown), the electric gas valve being switchable to an “on” position. The fourth step 640 of igniting a flame comprises the user closing the cap 110, thereby extinguishing the flame and the control unit 210 deactivating the fingerprint sensor, e.g., sleep mode.

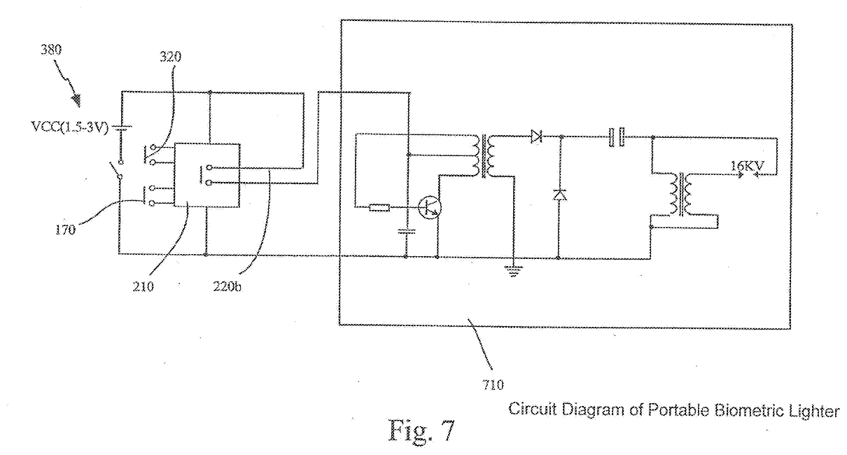

Referring to FIG. 7, a circuit diagram of the portable biometric lighter device 100 is shown, in accordance with the embodiment of FIG. 1. The portable biometric lighter device 100 comprises a control unit 210, a power source 380, a control line 220b, a set switch 170, an exemplary pulse igniter circuit 710, and an active switch 320. The power source 380 continuously provides power to the control unit 210.

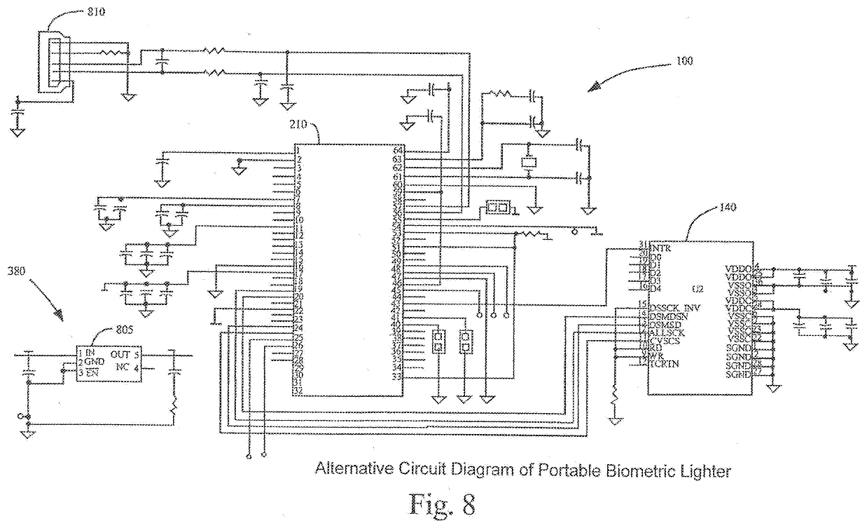

Referring to FIG. 8, an alternative circuit diagram of the portable biometric lighter device 100 is illustrated, in accordance with the embodiment of FIG. 1. In particular, device 100 is shown having control unit 210 coupled to fingerprint sensor 140. In the depicted embodiment, control unit 210 may be implemented using a microcontroller such as the ARM thumb-based microcontroller Model No. AT91SAM7S256, available from ARM, Inc., of Austin Texas. In addition, the fingerprint sensor 140 is shown implemented using the ATW210 fingerprint sensor available from Atrua Technologies, Inc., of Campbell California. FIG. 8 also shows USB port 810 coupled to leads 56 and 57 of control unit 210.

Power source 380 is shown providing power to voltage regulator 805. The voltage regulator is shown implemented using the TPS76933 voltage regulator provided by Texas Instruments of Dallas, Texas. It is understood that during operation of voltage regulator 805, a reference voltage of 1.7V or greater on input 3 will disable the internal circuitry of the voltage regulator, thus significantly reducing the supply current via output 5. On the other hand, a voltage of less than 0.9 V on input 3 will enable the voltage regulator and will enable operation of the controlled devices (e.g., control unit 210 and fingerprint sensor 140). Accordingly, in the embodiment of FIG. 8, the power source 380 does not provide power to the control unit 210 and the fingerprint sensor 140 until a user flips open the cap 110 that activates the gas lever 350 and the active switch 320 or the user depresses the set switch 170.

TABLE 1

| | |
|---|---|
| 1 | ADVREF |
| 2 | GND |
| 3 | AD4 |
| 4 | AD5 |
| 5 | AD6 |
| 6 | AD7 |
| 7 | VDDIN |
| 8 | VDDOUT |
| 9 | PA17/PGMD5/AD0 |
| 10 | PA18/PGMD6/AD1 |
| 11 | PA21/PGMD9 |
| 12 | VDDCORE |
| 13 | PA19/PGMD7/AD2 |
| 14 | PA22/PGMD10 |
| 15 | PA23/PGMD11 |
| 16 | PA20/PGMD8/AD3 |
| 17 | GND |
| 18 | VDDIO |
| 19 | PA16/PGMD4 |
| 20 | PA15/PGMD3 |
| 21 | PA14/PGMD2 |
| 22 | PA13/PGMD1 |
| 23 | PA24/PGMD12 |
| 24 | VDDCORE |
| 25 | PA25/PGMD13 |
| 26 | PA26/PGMD14 |
| 27 | PA12/PGMD0 |
| 28 | PA11/PGMM3 |
| 29 | PA10/PGMM2 |
| 30 | PA9/PGMM1 |
| 31 | PA8/PGMM0 |
| 32 | PA7/PGMNVALID |
| 33 | TDI |
| 34 | PA6/PGMNOE |
| 35 | PA5/PGMRDY |
| 36 | PA4/PGMNCMD |
| 37 | PA27/PGMD15 |
| 38 | PA28 |
| 39 | NRST |
| 40 | TST |
| 41 | PA29 |
| 42 | PA30 |
| 43 | PA3 |
| 44 | PA2/PGMEN2 |
| 45 | VDDIO |
| 46 | GND |
| 47 | PA1/PGMEN1 |
| 48 | PA0/PGMEN0 |
| 49 | TDO |
| 50 | JTAGSEL |
| 51 | TMS |
| 52 | PA31 |
| 53 | TCK |
| 54 | VDDCORE |
| 55 | ERASE |
| 56 | DDM |
| 57 | DDP |
| 58 | VDDIO |
| 59 | VDDFLASH |
| 60 | GND |
| 61 | XOUT |
| 62 | XIN/PGMCK |
| 63 | PLLRC |
| 64 | VDDPLL |

Control unit 210 is shown with leads 1-33 along the left side of the control unit, and leads 34-64 continuing along the opposing side. Table 1 setout below includes a pinout of the leads implemented by control unit 210.

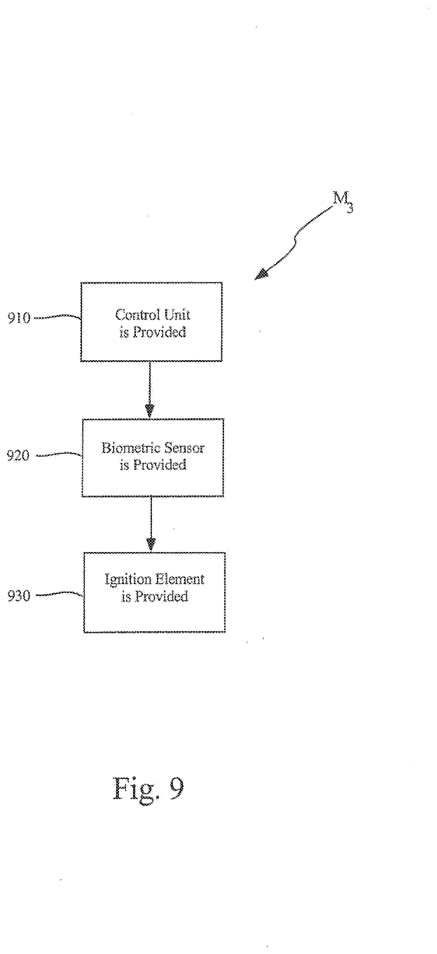

Referring to FIG. 9, a method M₃ of fabricating a portable biometric lighter device 100 is shown, the method M₃ comprising the steps of: providing a control unit 210, as indicated by block 910; providing a biometric sensor, e.g., a fingerprint sensor 140, wherein the biometric sensor providing step comprises configuring the biometric sensor to scan biometric data of a user and operably coupling the biometric sensor to the control unit 210, as indicated by block 920; and providing an ignition element, wherein the ignition element providing step comprises rendering the ignition element activable by the control unit 210 upon a match of the scanned biometric data of the user and biometric data of an authorized user that is stored in a memory device, as indicated by block 930, wherein the biometric sensor providing step comprises providing a fingerprint sensor 140, wherein the biometric sensor providing step comprises providing biometric data, and wherein the biometric data providing step comprises providing a fingerprint, wherein the biometric data of the authorized user providing step comprises providing a fingerprint, and wherein the ignition element providing step comprises providing a piezoelectric pulse igniter.

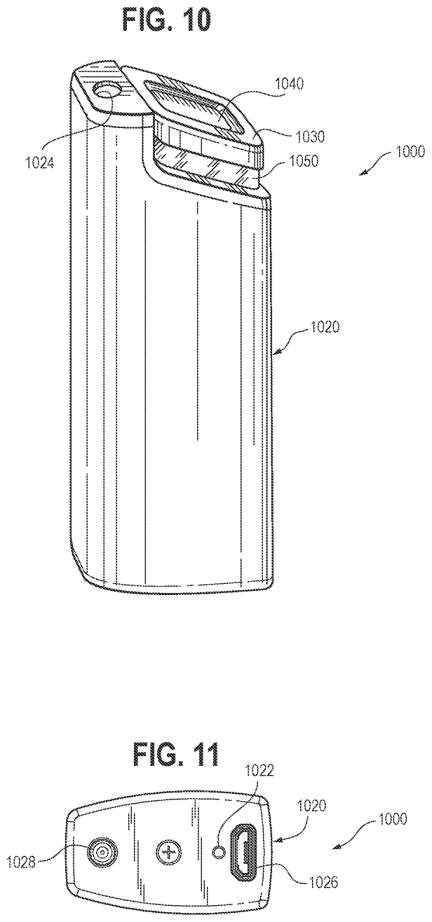

Referring to FIG. 10, a portable biometric lighter 1000 includes a body 1020, a fingerprint sensor 1040, and an LED 1050, and an opening 1024 for emitting a flame. The portable biometric lighter 1000 is shown in FIG. 10 as a cigarette/cigar lighter type, by way of example only, and it will be appreciated that the portable biometric lighter 1000 can be configured as a utility lighter, a barbeque lighter, and an oil-lighter. The portable biometric lighter 1000 can be disposable, e.g., wherein the user disposes of the portable biometric lighter 1000 after the lighter fluid or the power source is expended, or a reusable type, e.g., wherein the user can replace the power source and/or refill the lighter fluid. The lighter fluid may comprise at least one flammable component, such a butane gas, aliphatic hydrocarbon, a kerosene, a paraffinic hydrocarbon, a napthenic hydrocarbon, a benzene, a terpene, a terpenoid, a methanol, an ethanol, a propanol, a butanol, an aliphatic naptha, a hexamine, a lacolene, and the like.

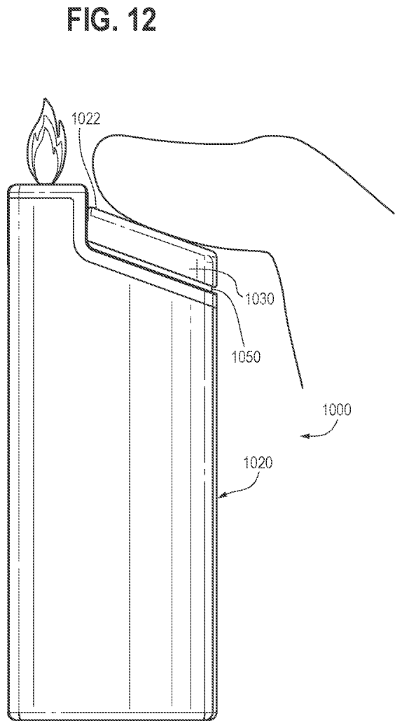

In the embodiment illustrated in FIG. 10, the portable biometric lighter 1500 includes a push-button 1530. The push-button 1530 is movably coupled to the body 1520 such that the push-button 1530 can move (by being depressed or released by a user) between a deactivated position of FIG. 10 to an activated position of FIG. 12. In some embodiments, the push-button 1530 is configured to activate the fingerprint sensor 1540 and allow lighter fluid to flow when the push-button 1530 is depressed. The push-button 1530 may be made of the same material as the body 1520, or may be made of a different material.

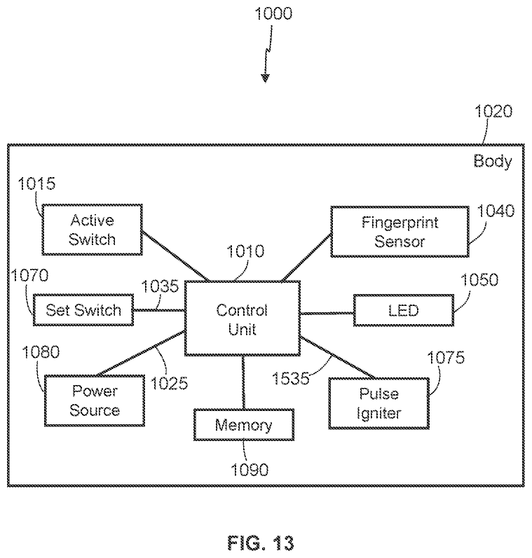

The body 1020 of the portable biometric lighter 1000 of FIG. 10 has a generally rectangular shape, but it will be appreciated that alternative embodiments of the portable biometric lighter 1000 may be of other shapes, for example, square, circular, cylindrical, tubular, oval, or the like. The body 1020 may be formed from any suitable material, for example, a polymer, a plastic, a metal, a heat-resistant material, a composite, or combinations thereof. With reference to FIGS. 10 and 13, in some embodiments, the body 1020 is configured to include one or more of the following elements: a fingerprint sensor 1040, an LED 1050, a control unit 1010, power lines 1025, control lines 1035, a set switch 1070, a gas lever (akin to the one shown in FIG. 3), an active switch 1015, a lighter fluid valve (akin to the one shown in FIG. 3), a nozzle (akin to the one shown in FIG. 3), a pulse igniter 1075, a pole (akin to the one shown in FIG. 3), a lighter fluid reservoir (akin to the one shown in FIG. 3), a power source 1080, and a memory 1090. As can be seen in FIG. 12, the body 1020 of the exemplary portable biometric lighter 1000 includes an aperture 1022 for providing access to the set switch 1070, an aperture 1026 for connecting a USB-based charger, and a turn-knob 1028 for adjusting the size of the flame emitted by the portable biometric lighter 1000.

In the exemplary embodiment illustrated in FIG. 13, the biometric (i.e., fingerprint) sensor 1040 of the portable biometric lighter 1000 is operably coupled to a control unit 1010. The biometric sensor 1040 is housed at least partially within the body 1520 but includes an exterior-facing fingerprint reading surface located at a top surface of the push-button 1030 that is accessible by a user and that is configured to scan an authorized user's biometric data (e.g., fingerprint) and any other user's biometric data (e.g., fingerprint), which may be stored in the memory 1090 of the portable biometric lighter 1000.

The LED 1050 of the portable biometric lighter 1000 is operably coupled to the control unit 1010 and is configured to provide indications to a user, via blinking and/or solid color or colors, the status of the portable biometric lighter functions including but not limited to setup/teaching mode, low battery, failed scan, and incorrect match. For example, in some embodiments, when the portable biometric lighter 1000 is ready to read a user's fingerprint, the LED 1050 is illuminated in a blue color, when the user's scanned fingerprint matches an authorized user fingerprint stored in the memory 1090, the LED 1050 is illuminated in a green color, and when the user's scanned fingerprint does not match an authorized user fingerprint stored in the memory 1090, the LED 1050 is illuminated in a red color.

The set switch 1070 of the portable biometric lighter 1000 is operably connected to the control unit 1010 and is housed in the body 1020. In the embodiment illustrated in FIGS. 10 and 13, the set switch 1070 is accessible through an aperture 1022 of the body 1020. In some embodiments, the set switch 1070 is configured to activate the control unit 1010 for accepting a new fingerprint, and to optionally erase a prior fingerprint from the memory device 1090 of the portable biometric lighter 1000 if the control unit 1510 is configured to allow erasing a prior fingerprint and accepting a new fingerprint.

With reference to FIG. 13, a power source 1080 is operably coupled to the control unit 1010 and is housed within the body 1020. In some embodiments, the power source 1080 is a primary cell battery, a rechargeable battery, a photo-voltaic cell, or the like. In the embodiment illustrated in FIG. 13, the power source 1080 provides power to the control unit 1010 and/or the fingerprint sensor 1040 via the power lines 1025, but in some approaches, the power source 1080 may be operatively coupled to the control unit 1010 and/or to the fingerprint sensor 1040 via suitable alternative means.

In the embodiment illustrated in FIGS. 10-13, the active switch 1015 is operably coupled to the fingerprint sensor 1040 such that upon a user pressing down on the push-button 1030, the gas lever of the portable biometric lighter 1000 is actuated and activates the active switch 1015 via contact force or electromagnetic force. The active switch 1015 upon activation then activates the fingerprint sensor 1040 to read or scan a fingerprint. In some embodiments, upon the user depressing the push-button 1030, the gas lever of the portable biometric lighter 1000 is also configured to lift a nozzle of the portable biometric lighter 1000, which allows the lighter fluid to be released from the lighter fluid valve.

A pulse igniter 1070, such as a piezoelectric based circuit, is configured to produce a high voltage spark from a pole of the portable biometric lighter 1000 to the nozzle of the portable biometric lighter 1000 upon the control unit 1010 determining a match between the scanned biometric data (e.g., fingerprint) of a user and the biometric data (e.g., fingerprint) of an authorized user, which is stored in the memory 1090 of the portable biometric lighter 1000. A flame is subsequently produced when the high voltage sparks come in contact with the lighter fluid that is flowing through the lighter fluid valve to the nozzle.

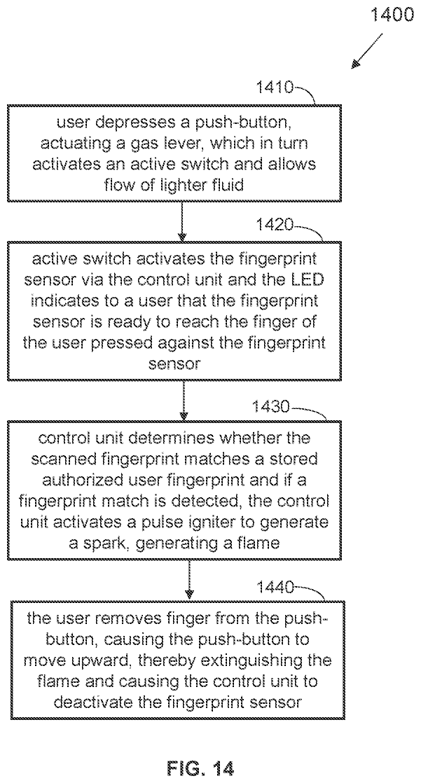

Referring to FIG. 14, a flowchart illustrates the steps of a method 1400 of activating, e.g., igniting a flame, by the portable biometric lighter 1000 depicted in FIGS. 10-13. The first step 1410 of the method 1400 of igniting a flame comprises a user placing a finger onto and depressing the push-button 1030, thereby actuating a gas lever, which in turn actuates an active switch 1015 via contact pressure or electromagnetic force. The actuation of the gas lever also causes a lifting of a nozzle, which allows lighter fluid to be released from the lighter fluid valve.

The second step 1420 of the method 1400 of igniting a flame comprises the active switch 1015, activating, via the control unit 1010, the fingerprint sensor 1040 to read or to scan a fingerprint and to indicate via the LED 1050 to the user that the fingerprint sensor 1040 is in “scan” or “read” mode. In the illustrated embodiment, the fingerprint sensor 1040 of the portable biometric lighter 1000 is located at an upper-facing surface of the push-button 1030, so while the user is depressing the push-button 1030, the user's thumb would be located on the fingerprint sensor 1040 enabling the fingerprint sensor 1040 to scan the user's thumb after the fingerprint sensor 1040 is activated.

The third step 1430 of the method 1400 of igniting the flame comprises the control unit 1010 determining whether the scanned fingerprint matches an authorized user's fingerprint that is stored in the memory 1090, and if the control unit 1010 determines that the scanned fingerprint matches an authorized user's fingerprint that is stored in the memory 1090, the control unit 1010 activates the pulse igniter 1070, e.g., a piezoelectric based circuit, thereby generating a plurality of high voltage sparks via the pole to the nozzle, thereby generating a flame via the lighter fluid flowing through the nozzle.

In some embodiments, when the control unit 1010 determines that the scanned fingerprint matches an authorized user's fingerprint that is stored in the memory 1090, the LED 1050 provides a color indication of a match (e.g., via a green color that is continuous or blinking). If, however, the control unit 1010 determines that the scanned fingerprint does not match an authorized user's fingerprint that is stored in memory, the LED 1050 will blink in a color (e.g., red) that indicates a mismatch or error, a flame is not emitted from the opening 1022 of the lighter 100, and the LED 1050 will revert to illuminating a color (e.g., blue) indicating the readiness of the fingerprint sensor 1040 to perform another scan of a user's finger.

With reference to FIG. 14, after the user has used the portable biometric lighter 1000 and wishes to deactivate the lighter 1000, the fourth step 1040 of the method 1000 of igniting a flame comprises the user removing his or her finger from the push-button 1030. This removal of the user's finger causes the push-button 1030 to move (due to an internal upward bias, for example, by a spring) from the activated position of FIG. 12 toward the deactivated position of FIG. 10, thereby extinguishing the flame and causing the control unit 1010 to deactivate the fingerprint sensor 1040 to place the fingerprint sensor 1540 in a sleep mode.

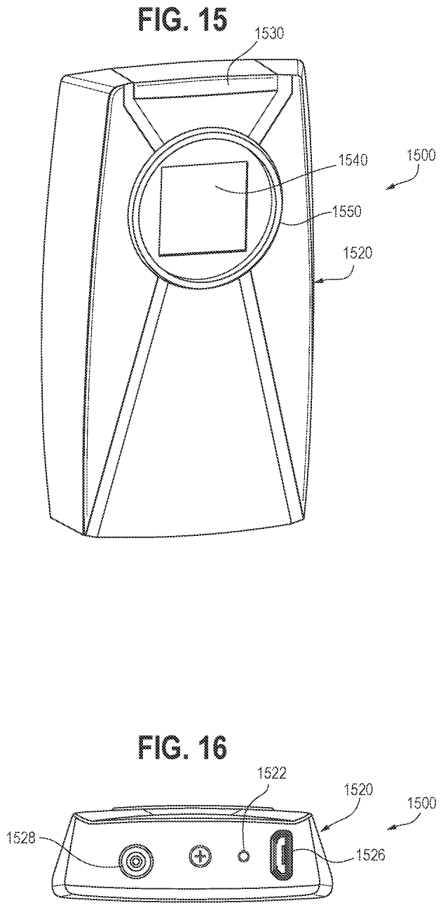

Referring to FIG. 15, a portable biometric lighter 1500 includes a cover 1530, a body 1520, a fingerprint sensor 1540, and an LED 1550. The portable biometric lighter 1500 is shown in FIG. 15 as a cigarette/cigar lighter type, by way of example only, and it will be appreciated that the portable biometric lighter 1500 can be configured as a utility lighter, a barbeque lighter, and an oil-lighter. The portable biometric lighter 1500 can be disposable, e.g., wherein the user disposes of the portable biometric lighter 1500 after the lighter fluid or the power source is expended, or a reusable type, e.g., wherein the user can replace the power source and/or refill the lighter fluid. The lighter fluid may comprise at least one flammable component, such a butane gas, aliphatic hydrocarbon, a kerosene, a paraffinic hydrocarbon, a napthenic hydrocarbon, a benzene, a terpene, a terpenoid, a methanol, an ethanol, a propanol, a butanol, an aliphatic naptha, a hexamine, a lacolene, and the like.

In the embodiment illustrated in FIG. 15, the portable biometric lighter 1500 includes a cover 1530. The cover 1530 is hingedly coupled to the body 1520 such that the cover 1530 can move from a closed position of FIG. 15 to an open position of FIG. 17, and is configured to prevent accidental activation of both a gas valve lever and an active switch of the portable biometric lighter 1500. In some embodiments, the cover 1530 is also configured to activate the fingerprint sensor 1540 and allow lighter fluid to flow when the cover 1530 is flipped open. The cover 1530 may be made of the same material as the body 1520, or may be made of a different material.

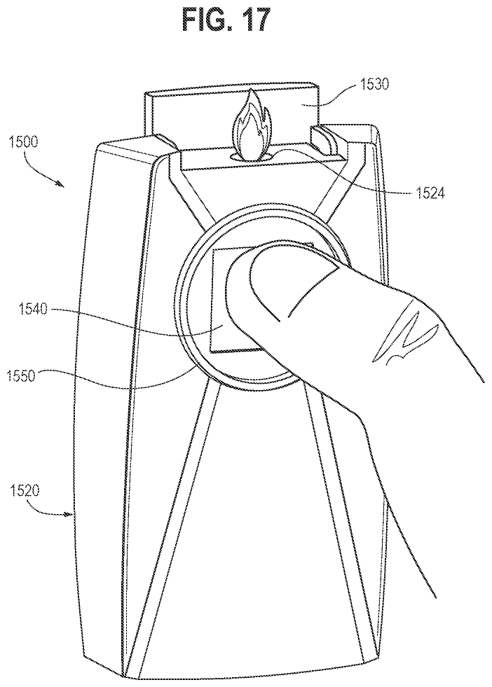

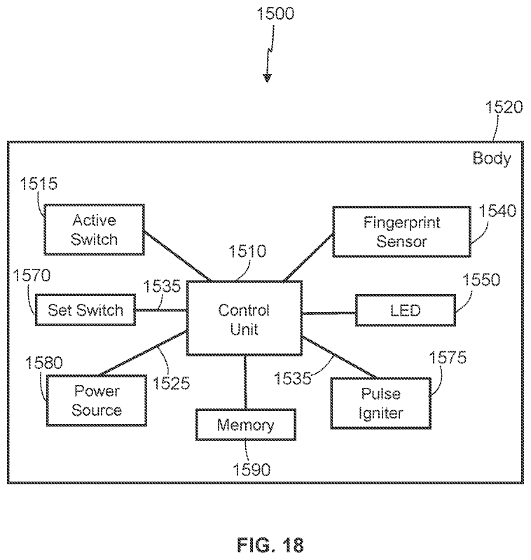

The body 1520 of the portable biometric lighter 1500 of FIG. 15 has a generally rectangular shape, but it will be appreciated that alternative embodiments of the portable biometric lighter 1500 may be of other shapes, for example, square, circular, cylindrical, tubular, oval, or the like. The body 1520 may be formed from any suitable material, for example, a polymer, a plastic, a metal, a heat-resistant material, a composite, or combinations thereof. With reference to FIGS. 15 and 18, in some embodiments, the body 1520 is configured to include one or more of the following elements: a fingerprint sensor 1540, an LED 1550, a control unit 1510, power lines 1525, control lines 1535, a set switch 1570, a gas lever (akin to the one shown in FIG. 3), an active switch 1515, a lighter fluid valve (akin to the one shown in FIG. 3), a nozzle (akin to the one shown in FIG. 3), a pulse igniter 1575, a pole (akin to the one shown in FIG. 3), a lighter fluid reservoir (akin to the one shown in FIG. 3), a power source 1580, and a memory 1090. As can be seen in FIG. 16, the body 1520 of the exemplary portable biometric lighter 1500 includes an aperture 1522 for providing access to the set switch 1570, an aperture 1526 for connecting a USB-based charger, and a turn-knob 1528 for adjusting the size of the flame emitted by the portable biometric lighter 1500.

In the exemplary embodiment illustrated in FIG. 18, the biometric (i.e., fingerprint) sensor 1540 of the portable biometric lighter 1500 is operably coupled to a control unit 1510. The biometric sensor 1540 is housed at least partially within the body 1520 but includes an exterior-facing fingerprint reading surface at a front face of the body 1520 that is accessible by a user and that is configured to scan an authorized user's biometric data (e.g., fingerprint) and any other user's biometric data (e.g., fingerprint), which may be stored in the memory 1590 of the portable biometric lighter 1500.

The LED 1550 of the portable biometric lighter 1500 of FIG. 18 is operably coupled to the control unit 1510 and is configured to provide indications to a user, via blinking and/or solid color or colors, the status of the portable biometric lighter functions including but not limited to setup/teaching mode, low battery, failed scan, and incorrect match. For example, in some embodiments, when the portable biometric lighter 1500 is ready to read a user's fingerprint, the LED 1550 is illuminated in a blue color, when the user's scanned fingerprint matches an authorized user fingerprint stored in the memory 1590, the LED 1550 is illuminated in a green color, and when the user's scanned fingerprint does not match an authorized user fingerprint stored in the memory 1590, the LED 1550 is illuminated in a red color.

The set switch 1570 of the portable biometric lighter 1500 is operably connected to the control unit 1510 and is housed in the body 1520. In the embodiment illustrated in FIGS. 15 and 18, the set switch 1570 is accessible through an aperture 1522 of the body 1520. In some embodiments, the set switch 1570 is configured to activate the control unit 1510 for accepting a new fingerprint, and to optionally erase a prior fingerprint from the memory device 1590 of the portable biometric lighter 1500 if the control unit 1510 is configured to allow erasing a prior fingerprint and accepting a new fingerprint.

With reference to FIG. 18, a power source 1580 is operably coupled to the control unit 1510 and is housed within the body 1520. In some embodiments, the power source 1580 is a primary cell battery, a rechargeable battery, a photo-voltaic cell, or the like. In the embodiment illustrated in FIG. 18, the power source 1580 provides power to the control unit 1510 and/or the fingerprint sensor 1540 via the power lines 1525, but in some approaches, the power source 1580 may be operatively coupled to the control unit 1510 and/or to the fingerprint sensor 1540 via suitable alternative means.

In the embodiment illustrated in FIGS. 15-18, the active switch 1515 is operably coupled to the fingerprint sensor 1540 such that upon a user flipping open the cover 1530, the gas lever of the portable biometric lighter 1500 is pulled up and activates the active switch 1515 via contact force or electromagnetic force. The active switch 1515 upon activation then activates the fingerprint sensor 1540 to read or scan a fingerprint. In some embodiments, upon the user flipping open the cover 1530, the gas lever of the portable biometric lighter 1500 is also configured to lift a nozzle of the portable biometric lighter 1500, which allows the lighter fluid to be released from the lighter fluid valve.

A pulse igniter 1570, such as a piezoelectric based circuit, is configured to produce a high voltage spark from a pole of the portable biometric lighter 1500 to the nozzle of the portable biometric lighter 1500 upon the control unit 1510 determining a match between the scanned biometric data (e.g., fingerprint) of a user and the biometric data (e.g., fingerprint) of an authorized user, which is stored in the memory 1590 of the portable biometric lighter 1500. A flame is subsequently produced when the high voltage sparks come in contact with the lighter fluid that is flowing through the lighter fluid valve to the nozzle.

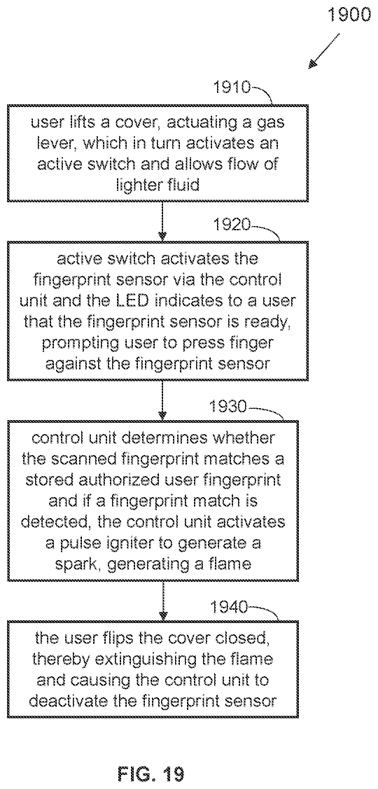

Referring to FIG. 19, a flowchart illustrates the steps of a method 1900 of activating, e.g., igniting a flame, by the portable biometric lighter 1500 depicted in FIGS. 15-18. The first step 1910 of the method 1900 of igniting a flame comprises a user opening a cap 1510, thereby actuating a gas lever, which in turn actuates an active switch 1515 via contact pressure or electromagnetic force. The actuation of the gas lever also causes a lifting of a nozzle, which allows lighter fluid to be released from the lighter fluid valve.

The second step 1920 of the method 1900 of igniting a flame comprises the active switch 1515, activating, via the control unit 1510, the fingerprint sensor 1540 to read or to scan a fingerprint and to indicate via the LED 1550 to the user that the fingerprint sensor 1540 is in “scan” or “read” mode, which prompts the user to press or swipe his or her finger against the fingerprint sensor 1540. The third step 1930 of the method 1900 of igniting the flame comprises the control unit 1510 determining whether the scanned fingerprint matches an authorized user's fingerprint that is stored in the memory 1590, and if the control unit 1510 determines that the scanned fingerprint matches an authorized user's fingerprint that is stored in the memory 1590, the control unit 1510 activates a pulse igniter 1570, e.g., a piezoelectric based circuit, thereby generating a plurality of high voltage sparks via the pole to the nozzle, thereby generating a flame via the lighter fluid flowing through the nozzle.

In some embodiments, when the control unit 1510 determines that the scanned fingerprint matches an authorized user's fingerprint that is stored in the memory 1590, the LED 1550 provides a color indication of a match (e.g., via a green color that is continuous or blinking). If, however, the control unit 1510 determines that the scanned fingerprint does not match an authorized user's fingerprint that is stored in memory, the LED 150 will blink in a color (e.g., red) that indicates a mismatch or error, a flame will not be emitted from the opening 1522, and the fingerprint sensor 1540 will subsequently revert to illuminating a color (e.g., blue) indicating the readiness of the fingerprint sensor 1540 to perform another scan of a user's finger. After the user has used the portable biometric lighter 1500 and wishes to deactivate the lighter 1500, the fourth step 1940 of the method 1900 of igniting a flame comprises the user closing the cover 1530, thereby extinguishing the flame and causing the control unit 1510 to deactivate the fingerprint sensor 1540 (e.g., place the fingerprint sensor 1540 in sleep mode).

Information as herein shown and described in detail is fully capable of attaining the above-described object of the invention, the presently preferred embodiment of the invention, and is, thus, representative of the subject matter which is broadly contemplated by the present invention. The scope of the present invention fully encompasses other embodiments which may become obvious to those skilled in the art, and is to be limited, accordingly, by nothing other than the appended claims, wherein reference to an element in the singular is not intended to mean “one and only one” unless explicitly so stated, but rather “one or more.” All structural and functional equivalents to the elements of the above-described preferred embodiment and additional embodiments that are known to those of ordinary skill in the art are hereby expressly incorporated by reference and are intended to be encompassed by the present claims.

Moreover, no requirement exists for a device or method to address each and every problem sought to be resolved by the present invention, for such to be encompassed by the present claims. Furthermore, no element, component, or method step in the present disclosure is intended to be dedicated to the public regardless of whether the element, component, or method step is explicitly recited in the claims. However, that various changes and modifications in form, material, and fabrication material detail may be made, without departing from the spirit and scope of the inventions as set forth in the appended claims, should be readily apparent to those of ordinary skill in the art. No claim herein is to be construed under the provisions of 35 U.S.C. § 112, sixth paragraph, unless the element is expressly recited using the phrase “means for.”

The present invention industrially applies to lighters and igniters. More specifically, the present invention industrially applies to portable biometric lighter devices. Even more specifically, the present invention industrially applies to portable biometric lighter devices using biometric data to prevent unauthorized usage, e.g., by a minor child.

Those skilled in the art will recognize that a wide variety of other modifications, alterations, and combinations can also be made with respect to the above described embodiments without departing from the scope of the invention, and that such modifications, alterations, and combinations are to be viewed as being within the ambit of the inventive concept.

What is claimed:

1. A portable biometric lighter device, comprising:
a body;
a battery power source housed within the body;
a control unit housed within the body, operably coupled to an igniter and to the battery power source;
a memory device housed within the body, coupled to the control unit and configured to store biometric data including fingerprints of authorized users;
a biometric sensor operably connected to the control unit and configured to scan biometric data of a user;
an actuator movably coupled to the body and configured to activate the biometric sensor when the actuator is moved from a deactivated position to an activated position;
a light source operably coupled to the control unit and configured to provide status indications of the biometric sensor; and
wherein the igniter is configured to ignite a flammable power source in response to being activated by the control unit upon a determination by the control unit that the biometric data of the user scanned by the biometric sensor matches the biometric data of any of the authorized users stored in the memory device.

2. The portable biometric lighter device of claim 1, wherein said biometric data further comprises at least one biometric data type selected from the group consisting of voice and facial image of at least one authorized user.

3. The portable biometric lighter device of claim 1, wherein the actuator is configured to activate the light source when the actuator is moved from the deactivated position to the activated position.

4. The portable biometric lighter device of claim 1, wherein the status indications include at least one selected from the group consisting of ready to scan the biometric data of the user, setup/teaching mode, low battery, failed scan, and incorrect match.

5. The portable biometric lighter device of claim 1, wherein the status indication is at least one of a color indication and a blinking indication.

6. The portable biometric lighter device of claim 1, wherein said biometric sensor further includes an exterior-facing biometric data reading surface located at a top surface of the actuator.

7. The portable biometric lighter device of claim 1, wherein:
said actuator is further configured to extinguish the ignited flammable power source in response to moving the actuator from the activated position to the deactivated position.

8. The portable biometric lighter device of claim 7, wherein:
said actuator is further configured to cause the control unit to deactivate the biometric sensor and place the biometric sensor in a sleep mode in response to moving the actuator to the deactivated position.

9. The portable biometric lighter device of claim 1, further comprising:
an active switch coupled to the actuator, the biometric sensor, and the control unit such that when the actuator is moved from the deactivated position to the activated position, the active switch activates the biometric sensor and the light source via the control unit.

10. The portable biometric lighter device of claim 9, wherein:
said active switch is further configured to activate a flammable power source lever that releases the flammable power source into a position for igniting by the igniter.

11. The portable biometric lighter device of claim 1, wherein:
said biometric sensor comprises a fingerprint sensor.

12. The portable biometric lighter device of claim 1, wherein:
said igniter is a piezoelectric pulse igniter.

13. A method for operating a portable biometric lighter device, comprising the steps of:
storing biometric data, including fingerprints of authorized users, in a memory device housed within a body of the portable biometric lighter device and coupled to a control unit housed within the body, wherein the control unit is additionally coupled to a battery power source housed within the body, an igniter, an actuator movably coupled to the body, a biometric sensor, and a light source;
moving, by a user, of the actuator from a deactivated position to an activated position;
in response to moving the actuator from the deactivated position to the activated position, activating by the control unit of the biometric sensor configured to scan biometric data of a user;
scanning biometric data of a user using the biometric sensor;
determining whether the biometric data of the user scanned by the biometric sensor matches the biometric data of any of the authorized users stored in the memory device; and
in response to the determining that the fingerprint of the user scanned by the biometric sensor matches the biometric data of any of the authorized users stored in the memory device, providing a matched user status indication using a light source operably coupled to the control unit and activating the igniter to ignite a flammable power source.

14. The method for operating the portable biometric lighter device of claim 13, further comprising the step of:
upon activating the biometric sensor, providing a ready to scan indication using the light source.

15. The method for operating the portable biometric lighter device of claim 13, further comprising the step of:
in response to the determining that the biometric data scanned by the biometric sensor does not match the biometric data of any of the authorized users stored in the memory device, providing an incorrect match status indication using a light source operatively coupled to the control unit.

16. The method for operating the portable biometric lighter device of claim 13, wherein said biometric sensor further includes an exterior-facing biometric data reading surface located at a top surface of the actuator, and said scanning biometric data of a user using the biometric sensor further comprises:
scanning the biometric data via the biometric data reading surface while the actuator is in the activated position.

17. The method for operating the portable biometric lighter device of claim 13, further comprising the step of:
moving the actuator from the activated position to the deactivated position, whereby the ignited flammable power source is extinguished.

18. The method for operating the portable biometric lighter device of claim 17, further comprising the step of:
upon moving the actuator from the activated position to the deactivated position, deactivating the biometric sensor and placing the biometric sensor in a sleep mode.

19. The method for operating the portable biometric lighter device of claim 13, wherein the portable biometric lighter device further comprises an active switch coupled to the actuator, the biometric sensor, and the control unit, and further comprising:
said activating by the control unit of the biometric sensor configured to scan biometric data of the user further comprising the active switch activating the biometric sensor via the control unit; and
said providing the matched user status indication using the light source further comprising the active switch activating the light source via the control unit.

20. The method for operating the portable biometric lighter device of claim 13, wherein:
said igniter is a piezoelectric pulse igniter.
